(19) United States
(12) Patent Application Publication
(10) Pub. No.: US 2010/0075442 A1
(43) Pub. Date: Mar. 25, 2010

(54) SEMICONDUCTOR WAFER PROCESSING APPARATUS, REFERENCE ANGULAR POSITION DETECTION METHOD, AND SEMICONDUCTOR WAFER

(76) Inventors: Yoshinori Hayashi, Kanagawa (JP); Hideki Mori, Kanagawa (JP)

Correspondence Address: KRATZ, QUINTOS & HANSON, LLP, 1420 K Street, N.W., Suite 400, WASHINGTON, DC, 20005, US

(21) Appl. No.: 12/597,635

(22) PCT Filed: Apr. 25, 2008
(86) PCT No.: PCT/JP2008/058097

§ 371 Date: Oct. 26, 2009

(30) Foreign Application Priority Data
Apr. 27, 2007 (JP) 2007-120173

(51) Int. Cl. H01L 21/66; B05C 11/00; H01L 29/02

(52) U.S. Cl. 438/14; 118/712; 257/618; 257/E29.002; 257/E21.53

(57) ABSTRACT

[Problems] To provide a semiconductor wafer processing apparatus and reference angular position detection method able to suitably detect a reference angular position for a semiconductor wafer for which a reference angular position is set and a semiconductor wafer for which a reference angular position is suitably set.

[Means for Solving Problems] A semiconductor wafer (100) is formed at part of an outer circumference edge part (101) with a crystal orientation detection flat surface (102) vertical to the diametrical direction at a position forming a predetermined angle with the crystal orientation. The semiconductor wafer processing apparatus successively captures images of the outer circumference edge part (101 of this semiconductor wafer (100) in the circumferential direction, generates first outer circumference bevel surface (101b) length data, outer circumference end face (101a) length data, and second outer circumference bevel surface (101c) length data expressing the outer circumference edge shape, and detects the angular position at which the first outer circumference bevel surface (101c) length data and second outer circumference bevel surface (101b) length data are minimum and the outer circumference end face (101a) length data is maximum as the reference angular position.

### TECHNICAL FIELD

The present invention relates to a semiconductor wafer processing apparatus for processing a semiconductor wafer set with a reference angular position in the circumferential direction while rotating it, a reference angular position detection method, and a semiconductor wafer to be processed by the semiconductor wafer processing apparatus.

### BACKGROUND ART

In the past, to enable identification of the crystal orientation of a semiconductor wafer, the method of forming a U-shaped or V-shaped notch at the outer edge has generally been used. With this method, the notch is formed so that the position of the notch becomes a predetermined angle with respect to the crystal orientation or otherwise the position of the notch and the crystal orientation satisfy a predetermined relationship. Further, to produce a so-called “notch-less wafer”, there is the method of replacing the formation of a notch with formation of a mark showing the crystal orientation on the main surface of the semiconductor wafer by laser marking (see Patent Literature 1). Furthermore, the method of applying the method of forming a mark expressing various information relating to the semiconductor wafer on the outer circumference end face of the semiconductor wafer (see Patent Literature 2) to form a mark showing the crystal orientation at the outer circumference end face may be considered.

Patent Literature 1: Japanese Patent Publication (A) No. 10-256106

Patent Literature 2: Japanese Patent Publication (A) No. 2002-353080

### DISCLOSURE OF THE INVENTION

### Technical Problem

However, in a semiconductor wafer with a notch formed at the outer edge, the part where that notch is formed and other parts differ in process conditions. For example, when forming a resist film on the front surface of the semiconductor wafer, the resist ends up circling around to the back surface from the part of the notch and possibly causing contamination of the back surface. Further, in the processing for shaping the end face applied to obtain uniform process conditions at the next process (for example, processing in the bevel CMP step or processing in the bevel polishing step), the part where the notch is formed greatly differs in structure from the other parts, so separate preparatory processing becomes necessary. This is inefficient.

Further, with the method of forming a mark showing the crystal orientation at the main surface of the semiconductor wafer by laser marking, there are the problems that the flatness near that mark cannot be maintained, the resist film or other coating film covering the front surface becomes easily peeled off by surface relief, and this becomes a source of generation of dust. Further, in recent years, along with the further density of semiconductor devices, there has been rising awareness that processing that might become a source of generation of dust is not desirable even at the outer circumference end face. In view of this, even with the method of forming a mark showing the crystal orientation at the outer circumference end face of a semiconductor wafer, similarly the surface relief near the mark will cause peeling of the coating film which can become a source of generation of dust, so this is not a desirable method. For this reason, it is being demanded to set an indicator showing a reference angular position for identifying the crystal orientation of a semiconductor wafer etc. without forming a notch or mark. Furthermore, it is being demanded to detect this reference angular position of a semiconductor wafer.

The present invention was made in view of this situation and provides a semiconductor wafer processing apparatus and reference angular position detection method enabling suitable detection of a reference angular position of a semiconductor wafer set with that reference angular position and a semiconductor wafer at which a reference angular position is suitably set.

### Technical Solution

The semiconductor wafer processing apparatus according to the present invention is a semiconductor wafer processing apparatus processing a semiconductor wafer set with a reference angular position at its circumferential direction while rotating it, having an outer circumference edge information generating means for detecting a shape or diameter of an outer circumference edge part at a plurality of rotational angular positions of the semiconductor wafer and generating outer circumference edge information showing the shape or diameter at the rotational angular positions and a reference angular position detecting means for detecting the reference angular position of the semiconductor wafer where the outer circumference edge part has a predetermined shape or has a predetermined diameter based on the outer circumference edge information generated for the plurality of rotational angular positions.

According to this configuration, when the shape or diameter of the outer circumference edge part and the reference angular position at the semiconductor wafer are linked, detecting that shape or diameter and, based on the information relating to these, that is, the outer circumference edge information, it is possible to detect the reference angular position of the semiconductor wafer.

Further, the semiconductor wafer processing apparatus according to the present invention may have a crystal orientation identifying means for identifying a crystal orientation of the semiconductor wafer based on a reference angular position detected by the reference angular position detecting means.

According to this configuration, when the reference angular position and the crystal orientation at the semiconductor wafer are linked, it is possible to identify the crystal orientation based on the detected reference angular position.

Further, in the semiconductor wafer processing apparatus according to the present invention, the outer circumference edge information generating means may have an imaging unit arranged facing an outer circumference edge part of the semiconductor wafer, capturing an image of the outer circumference edge part in the circumferential direction, and outputting an image signal and an image information generating means for generating image information of the outer circumferential edge part of the semiconductor wafer from the image signal output from the imaging unit and may generate information showing the shapes at the plurality of rotational angular positions of the outer circumference edge part from the image information as the outer circumference edge information.

According to this configuration, image information showing the outer circumference edge part of the semiconductor wafer is generated and outer circumference edge information showing the shape of the outer circumference edge part is generated from that image information, so it is possible to accurately identify the shape of the outer circumference edge part.

Further, in the semiconductor wafer processing apparatus according to the present invention, the imaging unit may capture images of a plurality of surfaces forming the outer circumference edge part and output corresponding image signals and the outer circumference edge information generating means may generate the outer circumference edge information from image information corresponding to the plurality of surfaces forming the outer circumference edge part.

The outer circumference edge part of a general semiconductor wafer is comprised of a plurality of surfaces such as an outer circumference end face, an outer circumference bevel surface slanted from an outer edge of one main surface (first main surface), and a second outer circumference bevel surface slanted from an outer edge of another main surface (second main surface). In this case, due to the above-mentioned configuration, by capturing images of the plurality of surfaces forming the outer circumference edge part and generating outer circumference edge information from the image information corresponding to the surfaces, it becomes possible to accurately identify shapes of the outer circumference edge part from that outer circumference edge information.

Further, in the semiconductor wafer processing apparatus according to the present invention, the outer circumference edge information generating means may generate information showing the shapes of the plurality of rotational angular positions of the semiconductor wafer as the outer circumference edge information, and the reference angular position detecting means may detect a rotational angular position giving a predetermined diameter as the reference angular position based on the outer circumference edge information at the different rotational angular positions.

According to this configuration, when a predetermined diameter is reached at the reference angular position in a semiconductor wafer under inspection, the diameters at the different rotational angular positions are judged from the outer circumference edge information showing the shapes at the plurality of rotational angular positions and the reference angular position giving the predetermined diameter is detected.

Further, in the semiconductor wafer processing apparatus according to the present invention, the outer circumference edge information generating means may have a light projecting unit arranged facing a first main surface side of the outer circumference edge part of the semiconductor wafer and projecting light to the outer circumference edge part and its vicinity and a light receiving unit arranged facing a second main surface side of the outer circumference edge part of the semiconductor wafer and receiving light from the light projecting unit and may generate information showing the diameters at the rotational angular positions from the light receiving state of the light receiving unit as the outer circumference edge information.

According to this configuration, when the light projecting unit projects light to the outer circumference edge part and its vicinity, part of that light is reflected by the semiconductor wafer (outer circumference edge part), and the light receiving unit receives the light passed through without being reflected, so the diametrical direction position of the outer circumference edge part may be identified by that light receiving state and the diameter of the semiconductor wafer can be obtained from that diametrical direction position.

Further, in the semiconductor wafer processing apparatus according to the present invention, the outer circumference edge information generating means may have an imaging unit arranged facing a first main surface side of the outer circumference edge part of the semiconductor wafer, successively capturing images of the outer circumference edge part in the circumferential direction, and outputting image signals and an image information generating means for generating image information of the outer circumference edge part from the image signals from the imaging unit and may generate information showing the diameters at the plurality of rotational angular positions from the image information as the outer circumference edge information.

According to this configuration, the diametrical direction position of the outer circumference edge part may be identified from image information obtained by capturing images, and the diameter of the semiconductor wafer may be obtained from that diametrical direction position.

The reference angular position detection method of a semiconductor wafer according to the present invention is a method detecting a reference angular position when processing a semiconductor wafer set with a reference angular position at its circumferential direction while rotating it, having an outer circumference edge information generation step of detecting a shape or diameter of an outer circumference edge part at a plurality of rotational angular positions of the semiconductor wafer and generating outer circumference edge information showing the shape or diameter at the rotational angular positions and a reference angular position detection step of detecting the reference angular position of the semiconductor wafer where the outer circumference edge part becomes a predetermined shape or becomes a predetermined diameter based on the outer circumference edge information generated for the plurality of rotational angular positions.

Further, in the reference angular position inspection method according to the present invention, the outer circumference edge information generation step may generate information showing the diameter at the outer circumference edge part as outer circumference edge information and the reference angular position detection step may detect a rotational angular position giving a predetermined diameter as the reference angular position based on the outer circumference edge information at the different rotational angular positions.

The semiconductor wafer according to the present invention is a semiconductor wafer to be processed by the above-mentioned semiconductor wafer processing apparatus wherein a shape at a reference angular position of an outer circumference edge part formed of a first outer circumference bevel surface slanted from an outer edge of a first main surface, a second outer circumference bevel surface slanted from an outer edge of a second main surface at an opposite side from the first main surface, and an outer circumference end face differs from the shapes at the other angular positions within a range not influencing the shapes of the first main surface and the second main surface.

According to this configuration, the shape at the reference angular position of the outer circumference edge part differs from the shapes at the other angular positions within a range not influencing the shapes of the first main surface (for example, round flat surface of front side) and second main surface (for example, round flat surface of back side), so by detecting the shape of that outer circumference edge part at the reference angular position, it becomes possible to detect that reference angular position. Further, the difference between the shape at the reference angular position and the shapes at the other angular positions is within a range not influencing the shapes of the first main surface and second main surface, so the part of that reference angular position will not greatly differ from the other parts in process conditions or structure like with a U-shaped or V-shaped notch ending up influencing the shapes of the first main surface and second main surface. Therefore, the shape at that reference angular position will not become a cause of contamination or render the processing for shaping the end face inefficient and, furthermore, will not become a source of generation of dust like with a mark, so can serve as a suitable indicator showing the reference angular position.

Further, in the semiconductor wafer according to the present invention, the outer circumference edge part may be partially cut away at the reference angular position in a direction vertical to the diametrical direction of that semiconductor wafer within a range not influencing the shapes of the first main surface and the second main surface and a flat surface different from shapes at the other angular positions may be formed at the reference angular position of the outer circumference end face.

According to this configuration, the reference angular position may be detected by detecting the flat surface formed at the outer circumference end face by partially cutting away the outer circumference edge part in a direction vertical to the diametrical direction of that wafer within a range not influencing the shapes of the first main surface and second main surface.

Further, the semiconductor wafer according to the present invention is a semiconductor wafer to be processed by the above-mentioned semiconductor wafer processing apparatus where the outer circumference end face is formed into a uniform continuous curved surface and where the value of the diameter at the reference position differs from the values of the diameters at other angular positions.

According to this configuration, by detecting a specific value of the diameter different from the values of the diameters at other angular positions, it becomes possible to detect the reference angular position of the semiconductor wafer. Further, it is possible to detect the reference angular position by the value of the diameter at a semiconductor wafer with an outer circumference end face formed by a uniform continuous curved surface, so the part of that reference angular position will not greatly differ from the other parts in process conditions or structure like with a U-shaped or V-shaped notch impairing the uniform continuous curved surface of the outer circumference end shape. Therefore, the part at that reference angular position will not become a cause of contamination or render the processing for shaping the end face inefficient and, furthermore, will not become a source of generation of dust like with a mark, so can serve as a suitable indicator showing the reference angular position.

Furthermore, in the semiconductor wafer according to the present invention, the value of the diameter can be made maximum or minimum at the reference angular position. Due to this, it is possible to identify the reference angular position by detecting the angular position where the value of the diameter becomes maximum or minimum.

Further, the semiconductor wafer according to the present invention is a semiconductor wafer to be processed by the above-mentioned semiconductor wafer processing apparatus wherein at an outer circumference edge part formed of a first outer circumference bevel surface slanted from an outer edge of a first main surface, a second outer circumference bevel surface slanted from an outer edge of a second main surface at an opposite side from the first main surface, and an outer circumference end face, a width of the diametrical direction of the first outer circumference bevel surface and a width of the diametrical direction of the second outer circumference bevel surface at the reference angular position differ from the corresponding widths of the diametrical direction at other angular positions.

According to this configuration, it becomes possible to detect the reference angular position of the semiconductor wafer by detecting corresponding widths of the diametrical direction differing from the width of the diametrical direction of the first outer circumference bevel surface and the width of the diametrical direction of the second outer circumference bevel surface at other angular positions. Further, since it is possible to detect the reference angular position by the width of the diametrical direction of the first outer circumference bevel surface and the width of the diametrical direction at the second outer circumference bevel surface at the outer circumference edge part, the part of that reference angular position will not greatly differ from the other parts in process conditions or structure like with a U-shaped or V-shaped notch impairing the shape of the outer circumference edge part. Therefore, the part at that reference angular position will not become a cause of contamination or render the processing for shaping the end face inefficient and, furthermore, will not become a source of generation of dust like with a mark, so can serve as a suitable indicator showing the reference angular position.

Further, in the semiconductor wafer according to the present invention, the width of the diametrical direction of the first outer circumference bevel surface and the width of the diametrical direction of the second outer circumference bevel surface at the reference angular position can be made maximum or minimum. Due to this, it becomes possible to identify the reference angular position by detecting the angular position at which the width of the diametrical direction of the first outer circumference bevel surface and the width of the diametrical direction of the second outer circumference bevel surface become maximum.

### ADVANTAGEOUS EFFECTS OF THE INVENTION

According to the present invention, when the shape or diameter of the outer circumference edge part in a semiconductor wafer and the reference angular position are linked, detecting that shape or diameter and, based on the information relating to the same, that is, the outer circumference edge information, it is possible to detect the reference angular position of the semiconductor wafer.

### BRIEF DESCRIPTION OF THE DRAWINGS

FIG. 1 is a perspective view of the appearance of a semiconductor wafer according to an embodiment of the present invention.

FIG. 2A is a top view of a first detailed example of the configuration of the semiconductor wafer shown in FIG. 1 (first semiconductor wafer).

FIG. 2B gives a cross-sectional view along the line A-A (a) and a cross-sectional view along the line B-B of FIG. 2A

FIG. 3A is a top view of a second detailed example of the configuration of the semiconductor wafer shown in FIG. 1 (second semiconductor wafer).

FIG. 3B gives a cross-sectional view along the line A-A (a) and a cross-sectional view along the line B-B of FIG. 3A

FIG. 4A is a top view of a third detailed example of the configuration of the semiconductor wafer shown in FIG. 1 (third semiconductor wafer).

FIG. 4B gives a cross-sectional view along the line A-A (a) and a cross-sectional view along the line B-B of FIG. 4A

FIG. 5 is a block diagram schematically showing main parts of a semiconductor wafer processing apparatus according to an embodiment of the present invention.

FIG. 6 is a view schematically showing an example of the arrangement of three CCD cameras (imaging units) with respect to a semiconductor wafer in a semiconductor wafer processing apparatus.

FIG. 7 is a view schematically showing another example of an imaging unit in a semiconductor wafer processing apparatus.

FIG. 8 is a flow chart showing an image acquiring operation according to a processing unit.

FIG. 9 is a view for explaining an angular position of a semiconductor wafer.

FIG. 10 is a view showing correspondence between an imaging location of a semiconductor wafer and an image.

FIG. 11 is a flow chart showing an outer circumference edge shape detection operation by a processing unit.

FIG. 12 is a flow chart showing a crystal orientation detection operation by a processing unit in the case of inspecting a first semiconductor wafer.

FIG. 13 is a view showing a first example of the configuration of angle information.

FIG. 14 is a view showing an image of a first outer circumference bevel surface of a first semiconductor wafer, an image of an outer circumference end face, an image of a second outer circumference bevel surface, and a correspondence with first outer circumference bevel surface length data, outer circumference end face length data, and second outer circumference bevel surface length data.

FIG. 15 is a flow chart showing a crystal orientation detection operation by a processing unit when inspecting a second semiconductor wafer.

FIG. 16 is a view showing a second example of configuration of angle information.

FIG. 17 is a view showing an image of a first outer circumference bevel surface of a second semiconductor wafer, an image of an outer circumference end face, an image of a second outer circumference bevel surface, and a correspondence with first outer circumference bevel surface length data, outer circumference end face length data, and second outer circumference bevel surface length data.

FIG. 18 is a view showing an example of arrangement of a light projecting unit and light receiving unit in a semiconductor wafer processing apparatus.

FIG. 19 is a flow chart showing a diameter detection operation by a processing unit based on a signal from a light receiving unit.

FIG. 20 is a flow chart showing a crystal orientation detection operation by a processing unit when inspecting a first semiconductor wafer.

FIG. 21 is a view showing changes of diameter data of a first semiconductor wafer with respect to movement of an angular position.

FIG. 22 is a flow chart showing a crystal orientation detection operation by a processing unit when inspecting second and third semiconductor wafers.

FIG. 23 is a view showing changes of diameter data of a second and third semiconductor wafer with respect to movement of an angular position.

FIG. 24 is a view schematically showing an example of the arrangement when using two sets of light projecting units and light receiving units.

FIG. 25 is a view schematically showing an example of the arrangement of cameras replacing the light projecting unit and light receiving unit.

### EXPLANATION OF REFERENCES

10 CCD camera
10a first CCD camera
10b second CCD camera
10c third CCD camera
10d camera lens
10e camera body
11, 13 light projecting unit
12, 14 light receiving unit
15, 16 CCD camera
20 the processing unit
31 first mirror
32 second mirror
33 correction lens
40 display unit
50 rotation drive motor
51 turntable
100-1 first semiconductor wafer
100-2 second semiconductor wafer
100-3 third semiconductor wafer
100a, 100b main surface
101 outer circumference edge part
101a outer circumference end face
101b first outer circumference bevel surface
101c second outer circumference bevel surface
102 crystal orientation detection flat surface

### BEST MODE FOR CARRYING OUT THE INVENTION

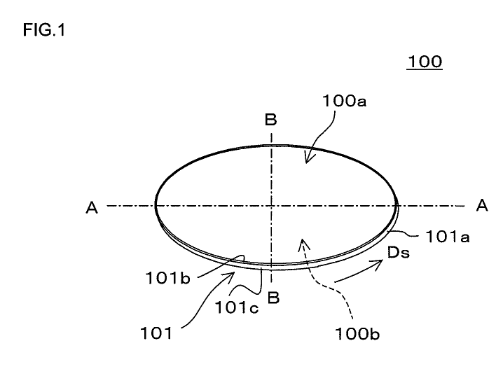

Below, embodiments of the present invention will be explained using the drawings. FIG. 1 is a perspective view of the appearance of a semiconductor wafer made of silicon under inspection according to an embodiment of the present invention.

A disk-shaped semiconductor wafer 100 shown in FIG. 1 is not formed with a notch as an indicator of a reference angular position for identifying a crystal orientation, that is, is a so-called “notch-less wafer”. An outer edge of this semiconductor wafer 100, that is, an outer circumference edge part 101, is comprised of an outer circumference end face 101a of the semiconductor wafer 100, a first outer circumference bevel surface 101b slanted from an outer edge of one main surface of the semiconductor wafer 100 (for example, a round shaped surface of the front side, first main surface) 100a, and a second outer circumference bevel surface 101c slanted from an outer edge of another main surface of the semiconductor wafer 100 (for example, a round shaped surface of the back surface side, second main surface) 100b.

Detailed examples of the configuration of three types of the semiconductor wafer 100 shown in FIG. 1 will be explained.

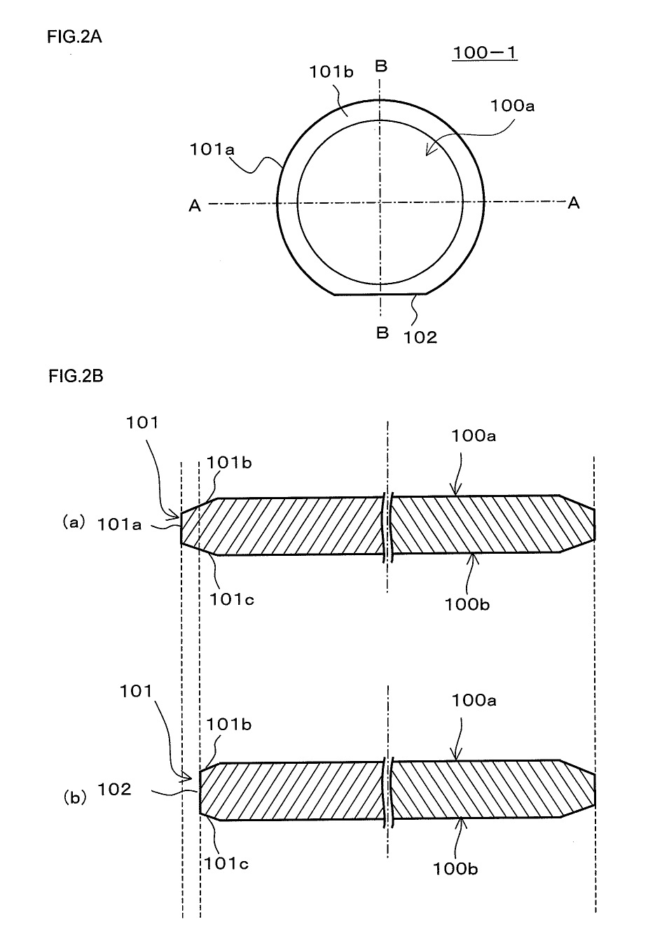

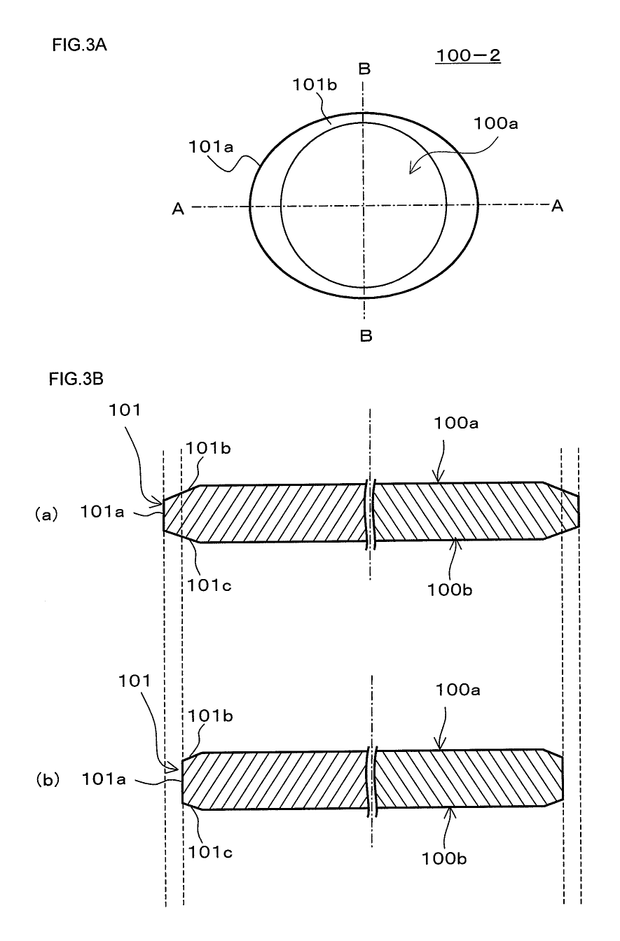

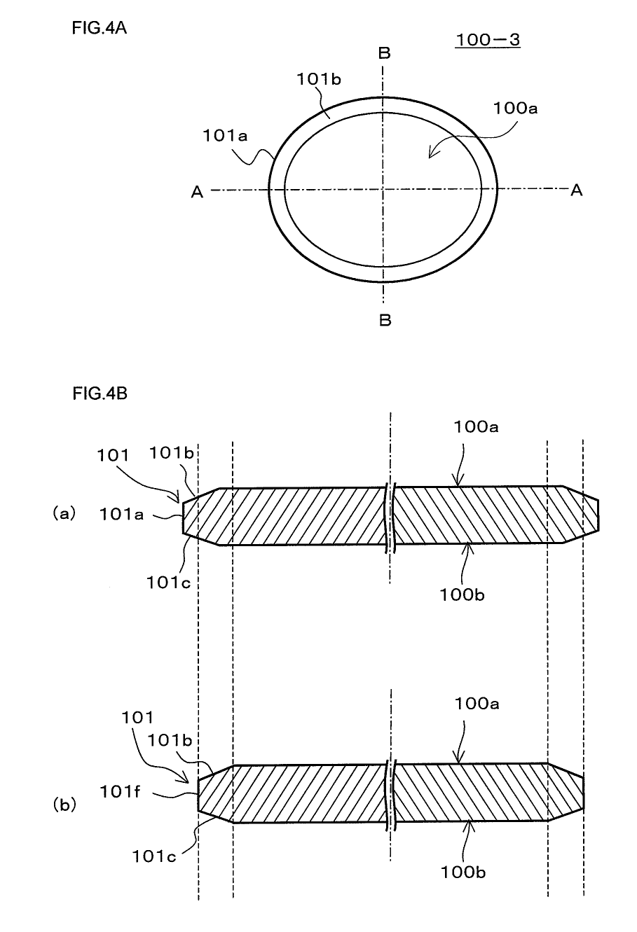

FIG. 2A is a top view of a first detailed example of the configuration of the semiconductor wafer 100 shown in FIG. 1 (below, referred to as “first semiconductor wafer 100-1”), while FIG. 2B gives a cross-sectional view along the line A-A (a) and a cross-sectional view along the line B-B of FIG. 2A. FIG. 3A is a top view of a second detailed example of the configuration of the semiconductor wafer 100 shown in FIG. 1 (below, referred to as “second semiconductor wafer 100-2”), while FIG. 3B gives a cross-sectional view along the line A-A (a) and a cross-sectional view along the line B-B of FIG. 3A. Further, FIG. 4A is a top view of a third detailed example of the configuration of the semiconductor wafer 100 shown in FIG. 1 (below, referred to as the “third semiconductor wafer 100-3”), while FIG. 4B gives a cross-sectional view along the line A-A (a) and a cross-sectional view along the line B-B of FIG. 4A. Note that the top views (FIG. 2A, FIG. 3A, and FIG. 4A) are shown emphasizing the outer circumference edge part 101 and do not accurately express the actual dimensions.

As shown in FIG. 2A and FIG. 2B, the outer circumference edge part 101 of the first semiconductor wafer 100-1 is partially cut away (part through which line B-B passes) in a direction vertical to the diametrical direction of the first semiconductor wafer 100-1 within a range not influencing the shapes (round shapes) of the first main surface 100a and second main surface 100b, that is, within a range not encroaching on the first main surface 100a and second main surface 100b, whereby a flat surface 102 is formed. This flat surface 102 is formed to a reference angular position predetermined as a position forming a predetermined angle with respect to the crystal orientation of the first semiconductor wafer 100-1. Specifically, the flat surface 102 is formed so that a line connecting a center part of that flat surface 102 and a center of the circle of the first semiconductor wafer 100-1 forms a predetermined angle with respect to the crystal orientation of the first semiconductor wafer 100-1 (may also match crystal orientation). Below, the flat surface 102 is called the “crystal orientation detection use flat surface 102”. Due to this configuration, at the reference angular position of the outer circumference edge part 101 where the crystal orientation detection use flat surface 102 is formed, the width of the outer circumference end face 101a (the width of that crystal orientation detection use flat surface 102: length in vertical direction in FIG. 2B (b)) becomes broader than the width of the outer circumference end face 101a at other angular positions, and the diametrical direction widths of the first outer circumference bevel surface 101b and second outer circumference bevel surface 101c become narrower than the diametrical direction widths at other angular positions.

Further, as shown in FIG. 3A and FIG. 3B, the second semiconductor wafer 100-2 has a diametrical direction length (width) of the outer circumference edge part 101 corresponding to the outsides of the first main surface 100a and second main surface 100b which is not constant at all angular positions in the circumferential direction and forms an elliptical shape overall. At the maximum diameter part, the width of the outer circumference end face 101a is narrower than other parts and the diametrical direction widths of the first outer circumference bevel surface 101b and second outer circumference bevel surface 101c are broader than other parts. On the other hand, at the minimum diameter part, the width of the outer circumference end face 101a is broader than other parts and the diametrical direction widths of the first outer circumference bevel surface 101b and second outer circumference bevel surface 101c are narrower than other parts. Further, the diametrical direction widths of the first outer circumference bevel surface 101b and second outer circumference bevel surface 101c become maximum at the parts through which the line A-A passes in FIG. 3A and becomes minimum at the parts through which the line B-B passes. The angular position in the circumferential direction where the diametrical direction widths of this first outer circumference bevel surface 101b and second outer circumference bevel surface 101c become either maximum or minimum is determined as the reference angular position forming a predetermined angle with respect to the crystal orientation of the second semiconductor wafer 100-2 (may match with crystal direction).

Further, as shown in FIG. 4A and FIG. 4B, the third semiconductor wafer 100-3 has a diametrical direction length (width) of the outer circumference edge part 101 which is held constant yet forms an elliptical shape overall. Further, the angular position in the circumferential direction at either that maximum diameter or minimum diameter is determined as the reference angular position forming a predetermined angle with respect to the crystal orientation (may match crystal orientation).

Next, the semiconductor wafer processing apparatus for obtaining the crystal orientation of the above-mentioned semiconductor wafers 100-1 to 100-3 (below, these semiconductor wafers 100-1 to 100-3 being suitably lumped together and referred to as the “semiconductor wafer 100”) will be explained.

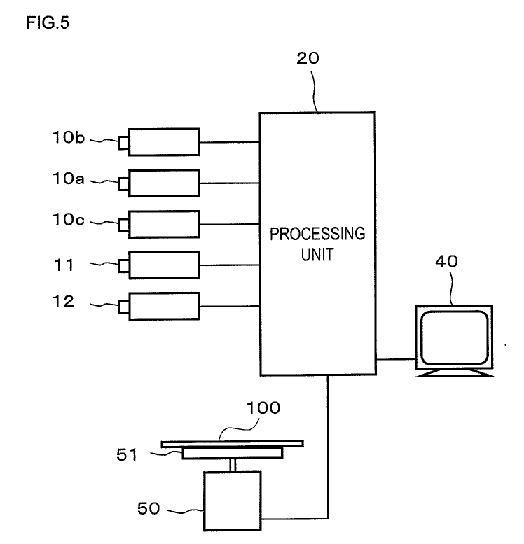

FIG. 5 is a view schematically showing the main parts of a semiconductor wafer processing apparatus. In the semiconductor wafer processing apparatus shown in FIG. 5, a first CCD camera 10a, second CCD camera 10b, and third CCD camera 10c and a light projecting unit 11 and light receiving unit 12 are connected to a processing unit 20 comprised of a computer. The processing unit 20 controls the drive operation of the rotation drive motor 50 so as to turn a turntable 51 having a semiconductor wafer 100 set by an alignment mechanism in a horizontal state by a predetermined speed. Further, the processing unit 20 processes the image signals successively output from the first CCD camera 10a, second CCD camera 10b, and third CCD camera 10c and, further, makes the light projecting unit 11 emit light and makes the light receiving unit 12 detect the light receiving state. The processing unit 20 has a display unit 40 connected to it. The processing unit 20 makes the display unit 40 display an image and so on based on the image information generated from the above-mentioned image signals.

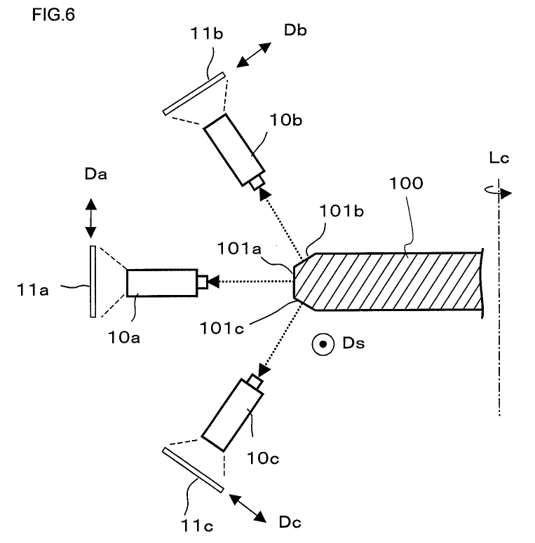

FIG. 6 is a view showing an example of the arrangement of three CCD cameras constituting the imaging unit in the semiconductor wafer processing apparatus, that is, a first CCD camera 10a, second CCD camera 10b, and third CCD camera 10c.

The semiconductor wafer 100, for example, is set on the turntable 51 (see FIG. 5) and can rotate together with that turntable 51 about its axis of rotation Lc. The three CCD cameras, that is, the first CCD camera 10a, the second CCD camera 10b, and the third CCD camera 10c, are set so as to face the outer circumference edge part 101 of the semiconductor wafer 100 set on the turntable 51. The first CCD camera 10a is set facing the end face (outer circumference end face) 101a of the outer circumference edge part 101 of the semiconductor wafer 100 in a direction so that an internal CCD line sensor 11a extends in a direction (Da) cutting across the outer circumference end face 101a substantially perpendicularly to the circumferential direction (Ds: direction vertical to paper surface in FIG. 6). The second CCD camera 10b is set facing the first outer circumference bevel surface 101b of the semiconductor wafer 100 in a direction so that an internal CCD line sensor lib extends in a direction (Db) cutting across the first outer circumference bevel surface 101b substantially perpendicularly to the circumferential direction (Ds). The third CCD camera 10c is set facing the second outer circumference bevel surface 101c of the semiconductor wafer 100 in a direction so that an internal CCD line sensor 11c extends in a direction (Dc) cutting across the second outer circumference bevel surface 101c substantially perpendicularly to the circumferential direction (Ds).

In the process of rotation of the semiconductor wafer 100, the CCD line sensor 11a of the first CCD camera 10a successively scans (sub scans) that outer circumference end face 101a in the circumferential direction (Ds). Due to this, the first CCD camera 10a successively captures images of that outer circumference end face 101a in the circumferential direction (Ds) and outputs image signals in pixel units. Further, in that process, the CCD line sensor 11b of the second CCD camera 10b successively scans (sub scans) the first outer circumference bevel surface 101b of the semiconductor wafer 100 in the circumferential direction (Ds) and the CCD line sensor 11c of the third CCD camera 10c successively scans (sub scans) the second outer circumference bevel surface 101c in the circumferential direction (Ds). Due to this, the second CCD camera 10b captures images of the first outer circumference bevel surface 101b and the third CCD camera 10c captures images of the second outer circumference bevel surface 101c in the circumferential direction (Ds) and outputs image signals in pixel units.

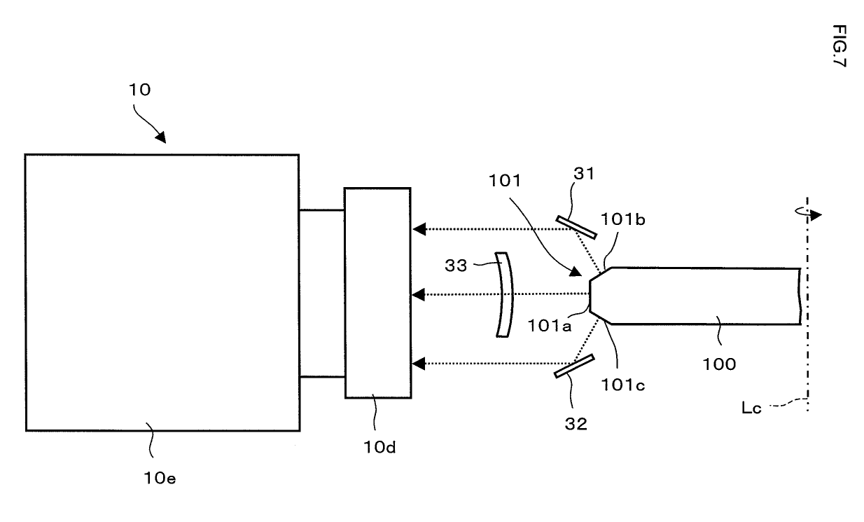

Note that the imaging unit capturing images of the outer circumference edge part 101 of the semiconductor wafer 100 does not have to be comprised of the three CCD cameras 10a, 10b, and 10c. For example, as shown in FIG. 7, it may also be comprised of a single CCD camera 10. In this case, a first mirror 31 is set near the first outer circumference bevel surface 101b at the outer circumference edge part 101 of the semiconductor wafer 100, while a second mirror 32 is set near the second outer circumference bevel surface 101c. The slants of the first mirror 31 and second mirror 32 are set so that the direction in which the image of the first outer circumference bevel surface 101b reflected at the first mirror 31 is led and the direction in which the image of the second outer circumference bevel surface 101c reflected at the second mirror 32 is led become parallel.

The CCD camera 10 has a camera lens 10d and a camera body 10e. The camera body 10e is provided with a CCD line sensor and is designed so that an image guided through the camera lens 10d is formed on that CCD line sensor. The CCD camera 10 has a field of vision including an outer circumference edge part 101 of the semiconductor wafer 100 and is arranged at a position so that an image of the first outer circumference bevel surface 101b and an image of the second outer circumference bevel surface 101c guided by the above-mentioned first mirror 31 and second mirror 32 are focused at the imaging surface of the CCD line sensor.

The image of the outer circumference end face 101a of the semiconductor wafer 100 is passed through the camera lens 10d of the CCD camera 10 and formed at the imaging surface of the CCD line sensor in the camera body 12. In this case, the length of the light path from the first outer circumference bevel surface 101b (second outer circumference bevel surface 101c) through the first mirror 31 (second mirror 32) to the CCD camera 10 and the length of the light path from the outer circumference end face 101a to the CCD camera 10 differ, so with that, the image of the outer circumference end face 101a is not focused at the imaging surface in the camera body 10e. Therefore, a correction lens 33 is set between the outer circumference end face 101a of the semiconductor wafer 100 and the CCD camera 10. Due to this correction lens 33 and camera lens 10d, the image of the outer circumference end face 101a of the semiconductor wafer 100 is guided to be focused at the imaging surface of the CCD line sensor in the camera body 10e.

In this way, due to the optical apparatus set between the CCD camera 10 and the outer circumference edge part 101 of the semiconductor wafer 100 (first mirror 31, second mirror 32, and correction lens 33), the images of the outer circumference end face 101a, first outer circumference bevel surface 101b, and second outer circumference bevel surface 101c of the outer circumference edge part 101 are led to be focused at the imaging surface of the CCD line sensor of the CCD camera 10. Due to this, the image signals successively output from the CCD camera 10 express the parts of the outer circumference end face 101a, first outer circumference bevel surface 101b, and second outer circumference bevel surface 101c.

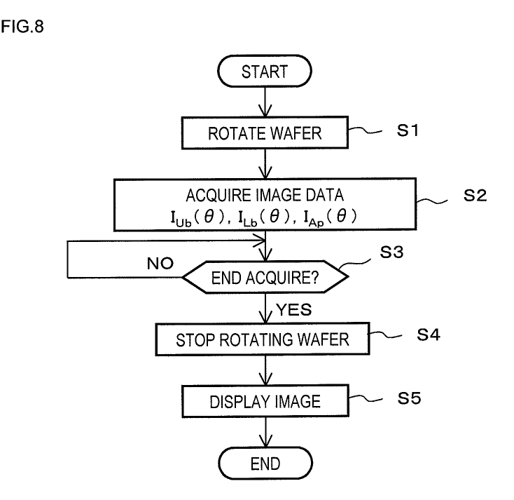

Next, the operation of the processing unit 20 based on the signals from the three CCD cameras 10a, 10b, and 10c will be explained. FIG. 8 is a flow chart showing the image acquiring operation by the processing unit 20.

The processing unit 20 makes the turntable 51 on which the semiconductor wafer 100 is set rotate by a predetermined speed (S1). In the process of the semiconductor wafer 100 rotating, the processing unit 20 receives as input the image signals successively output from the first CCD camera 10a, second CCD camera 10b, and third CCD camera 10c, generates image information showing the outer circumference edge part 101 of the semiconductor wafer 100 from these image signals (for example, darkness data of predetermined gradation levels for each pixel), and stores that image information (image data) in a predetermined memory (not shown) (S2).

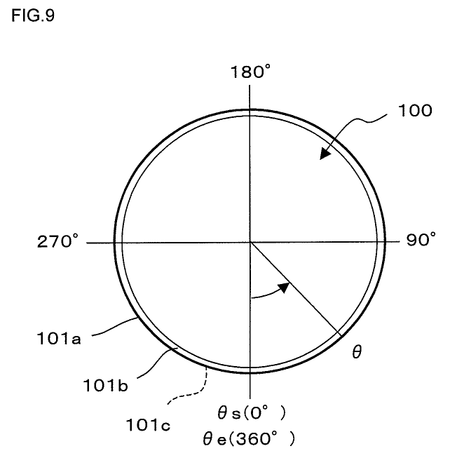

Specifically, from the image signal from the first CCD camera 10a, as shown in FIG. 9, image data I_{AP}(θ) showing the outer circumference end face 101a of the semiconductor wafer 100 at the different rotational angular positions θ of the circumferential direction (Ds) from the start position θs (θ=0°) to the same position one turn from the same, that is, the end position θe (360° (for example, the angle resolution corresponding to the width of the CCD line sensor 11a) is generated, from the image signal from the second CCD camera 10b, image data I_{Ub}(θ) showing the first outer circumference bevel surface 101b of the semiconductor wafer 100 at the different rotational angular positions θ is generated, and from the image signal from the third CCD camera 10c, image data I_{Lb}(θ) showing the second outer circumference bevel surface 101c of the semiconductor wafer 100 at the different rotational angular positions 8 is generated. Further, these image data I_{AP}(θ), I_{Ub}(θ), and I_{Lb}(θ) are stored in the memory in the state corresponding to that rotational angular position θ.

The processing unit 20, in the process of the above-mentioned processing, judges if image data of one turn of the semiconductor wafer 100 has finished been acquired (stored in the memory) (S3). If image data of one turn of the semiconductor wafer 100 has finished being acquired (YES at S3), the processing unit 20 stops the rotation of the turntable 51 at which the semiconductor wafer 100 is set (S4). After that, the processing unit 20 performs processing for displaying the image based on the acquired image data I_{AP}(θ), I_{Ub}(θ), and I_{Lb}(θ) (S5) and ends the series of processing.

Note that, when using the single CCD camera 10 shown in FIG. 7, the processing unit 20 cuts out from the image signal from the CCD camera 10 a signal part corresponding to the outer circumference end face 101a, a signal part corresponding to the first outer circumference bevel surface 101b, and a signal part corresponding to the second outer circumference bevel surface 101c and generates the image data I_{AP}(θ), I_{Ub}, (θ), and I_{Lb}(θ) showing the outer circumference end face 101a, first outer circumference bevel surface 101b, and second outer circumference bevel surface 101c from the signal parts.

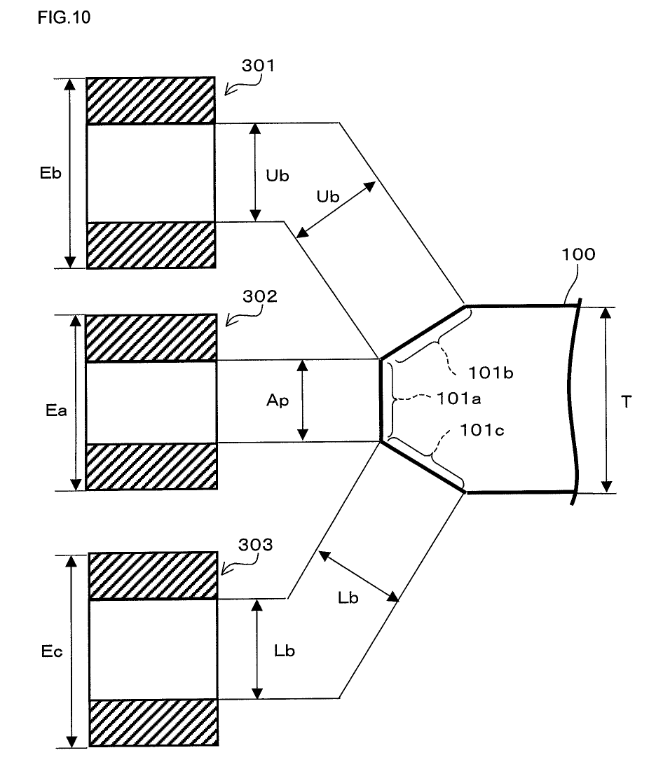

Due to the image display processing (S5), for example, as shown in FIG. 10, based on the image data I_{Ub}(θ) showing the first outer circumference bevel surface 101b of one turn of the semiconductor wafer 100, an image 301 of the first outer circumference bevel surface 101b in the field of vision Eb of the second CCD camera 10b is displayed on the display unit 40. Further, based on the image data I_{AP}(θ) showing the outer circumference end face 101a of one turn of the semiconductor wafer 100, an image 302 of the outer circumference end face 101a in the field of vision Ea of the first CCD camera 10a is displayed on the display unit 40, Furthermore, based on the image data I_{Lb}(θ) showing the second outer circumference bevel surface 101c of one turn of the semiconductor wafer 100, an image 303 of the second outer circumference bevel surface in the field of vision Ec of the third CCD camera 10c is displayed on the display unit 40.

Note that when the display unit 40 cannot display all of the images of one turn of the semiconductor wafer 100 for the first outer circumference bevel surface 101b, outer circumference end face 101a, and second outer circumference bevel surface 101c, it can display them by scrolling the images.

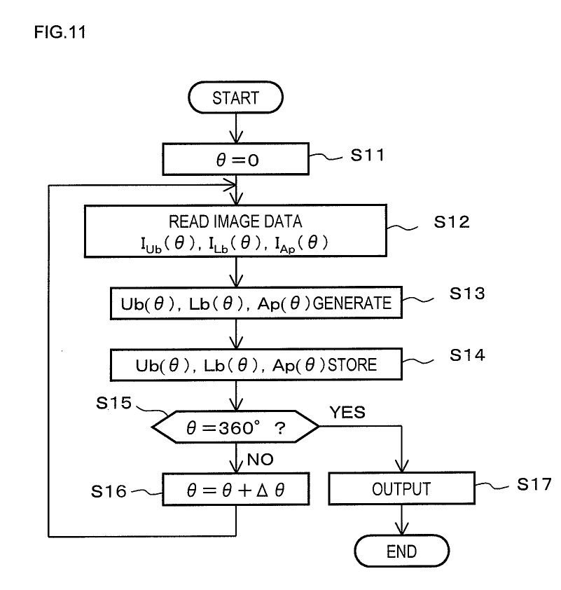

FIG. 11 is a flow chart showing an outer circumference edge shape detection operation according to the processing unit 20.

The processing unit 20, in response to a predetermined operation at an operation unit (not shown), sets the rotational angular position θ to an initial value (for example, θ=0°) (S11) and reads out the three types of image data I_{AP}(θ), I_{Ub}(θ), and I_{Lb}(θ) stored in the above-mentioned memory corresponding to this rotational angular position θ (S12).

Next, the processing unit 20, based on the image data I_{Ub}(θ) showing the first outer circumference bevel surface 101b, generates outer circumference edge information showing the shape of the first outer circumference bevel surface 101b at the rotational angular position θ (S13). Specifically, based on the state of change (change of darkness) of the image data I_{Ub}(θ) at the rotational angular position θ, the boundaries of the image of the first outer circumference bevel surface 101b (image 301 of FIG. 10) are detected. The first outer circumference bevel surface length data Ub(θ) expressed by the number of pixels between the boundaries of that image (or converted to distance by the pitch of pixels of the CCD line sensor 11b) is generated as the outer circumference edge information. This first outer circumference bevel surface length data Ub(θ) expresses the length of the first outer circumference bevel surface 101b in the direction cutting across the circumferential direction (Ds) at the rotational angular position θ substantially perpendicularly, in other words, the width of the first outer circumference bevel surface 101b in the direction vertical to the circumferential direction.

In the same way, the processing unit 20 generates outer circumference edge information showing the shape of the outer circumference end face 101a and outer circumference edge information showing the shape of the second outer circumference bevel surface 101c (S13). Specifically, regarding the shape of the outer circumference end face 101a, based on the state of change (change of darkness) of the image data I_{AP}(θ) at the rotational angular position θ, the boundaries of the image of the outer circumference end face 101a (image 302 of FIG. 10) are detected and outer circumference end face length data Ap(θ) expressed by the number of pixels between the boundaries of that image is generated as outer circumference edge information. This outer circumference end face length data Ap(θ) expresses the length of the outer circumference end face 101a in the direction cutting across the circumferential direction (Ds) at the rotational angular position θ substantially perpendicularly, in other words, the width of the outer circumference end face 101a in the direction vertical to the circumferential direction. Further, regarding the shape of the second outer circumference bevel surface 101c, based on the state of change (change of darkness) of the image data I_{Lb}(θ) at the rotational angular position 8, the boundaries of the image of the second outer circumference bevel surface 101c (image 303 of FIG. 10) are detected and second outer circumference bevel surface length data Lb(θ) expressed by the number of pixels between the boundaries of that image is generated as outer circumference edge information. This second outer circumference bevel surface length data Lb(θ) expresses the length of the second outer circumference bevel surface 101c in the direction cutting across the circumferential direction (Ds) at the rotational angular position θ substantially perpendicularly, in other words, the width of the second outer circumference bevel surface 101c in the direction vertical to the circumferential direction.

After that, the processing unit 20 stores the generated outer circumference edge information at the rotational angular position θ constituted by the first outer circumference bevel surface length data Ub(θ), outer circumference end face length data Ap(θ), and second outer circumference bevel surface length data Lb(θ) in a predetermined memory linked with that rotational angular position θ, and a cassette ID, a slot no., and a time stamp for identifying the semiconductor wafer 100 (S14). Furthermore, the processing unit 20 judges if the rotational angular position θ has reached 360° (θ=360°) or not (S15) and, if the rotational angular position θ has not reached 360° (NO at S15), decides not to end the one turn's worth of processing for the semiconductor wafer 100, and increases the rotational angular position θ by exactly a predetermined angle Δθ (θ=θ+Δθ:S16). Further, the processing unit 20 re-executes processing similar to the above-mentioned processing (S12 to S16) for that new rotational angular position θ. Due to this, the first outer circumference bevel surface length data Ub(θ), outer circumference end face length data Ap(θ), and second outer circumference bevel surface length data Lb(θ) at the new rotational angular position θ are stored in a predetermined memory linked with that rotational angular position θ (S14).

When it is judged that the rotational angular position θ has reached 360° (YES at S15), it is assumed that the one turn's worth of processing for the semiconductor wafer 100 has ended, and the processing unit 20 executes output processing (S17) and ends the series of processing.

In the output processing, for example, a graph on which the generated first outer circumference bevel surface length data Ub(θ), outer circumference end face length data Ap(θ), and second outer circumference bevel surface length data Lb(θ) are plotted so as to correspond to a plurality of rotational angular positions θ is displayed on the display unit 40 as the results of inspection.

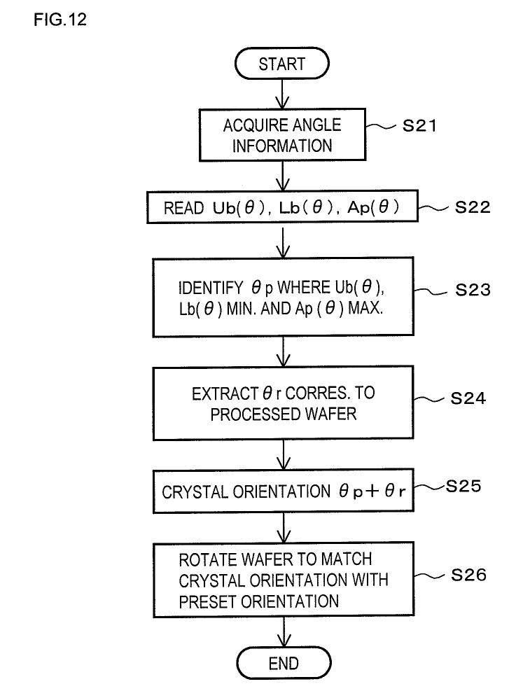

FIG. 12 is a flow chart showing the crystal orientation detection operation of the semiconductor wafer 100 by the processing unit 20. In this case, as the semiconductor wafer 100 under inspection, the first semiconductor wafer 100-1 (see FIG. 2A and FIG. 2B) is used.

The processing unit 20 obtains angle information, stored in the memory, including a predetermined angle formed by the position of the crystal orientation detection use flat surface 102 (reference angular position) and the crystal orientation (S21). The angle information is generated by an apparatus measuring the crystal orientation of the first semiconductor wafer 100-1 and is sent from that apparatus to this semiconductor wafer processing apparatus. Further, it is possible to load the angle information into this semiconductor wafer processing apparatus from an external medium recording the angle information in advance. Alternatively, the processing unit 20 obtains the angle information through a communication unit (not shown) or an interface of an external medium.

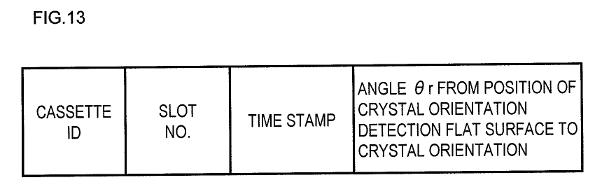

FIG. 13 is a view showing a first example of the angle information. The angle information shown in FIG. 13 is comprised of a cassette ID (identification information of cassette storing first semiconductor wafer 100-1), slot no. (number specifying slot storing the semiconductor wafer in the cassette), and time stamp for identifying the first semiconductor wafer 100-1 and an angle θr from a line connecting a center part of the crystal orientation detection use flat surface 102 of the first semiconductor wafer 100-1 and the center of the circle of that first semiconductor wafer 100-1 (reference angular position) to the crystal orientation of that first semiconductor wafer 100-1. The angle information acquired by the processing unit 20 is stored in the memory.

Returning to FIG. 12, next, the processing unit 20 reads out the first outer circumference bevel surface length data Ub(θ), outer circumference end face length data Ap(θ), and second outer circumference bevel surface length data Lb(θ) stored in the memory at step S14 shown in FIG. 11 (S22). Further, the processing unit 20 identifies the rotational angular position 8p where the values of the read out first outer circumference bevel surface length data Ub(θ) and second outer circumference bevel surface length data Lb(θ) become the minimum and the value of the outer circumference end face length data Ap(θ) becomes the maximum (S23).

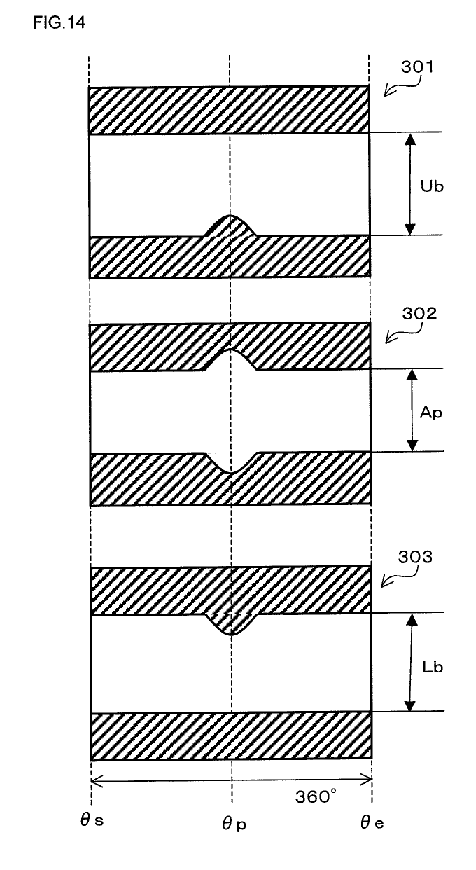

FIG. 14 is a view showing the image 301 of the first outer circumference bevel surface 101b, the image 302 of the outer circumference end face 101a, and the image 303 of the second outer circumference bevel surface 101c of the first semiconductor wafer 100-1 and the correspondence with the first outer circumference bevel surface length data Ub(θ), the outer circumference end face length data Ap(θ), and the second outer circumference bevel surface length data Lb(θ). As shown in FIG. 14, the image 301 of the first outer circumference bevel surface 101b, the image 302 of the outer circumference end face 101a, and the image 303 of the second outer circumference bevel surface 101c greatly change at the part corresponding to the rotational angular position θp. The values of the first outer circumference bevel surface length data Ub(θ) and second outer circumference bevel surface length data Lb(θ) become minimum, while the value of the outer circumference end face length data Ap(θ) becomes maximum. This means that a crystal orientation detection flat surface 102 having the rotational angular position θp of the outer circumference edge part 101 at its center is formed at that rotational angular position θp (see FIG. 2A and FIG. 2C). Therefore, the rotational angular position θp where the values of the first outer circumference bevel surface length data Ub(θ) and second outer circumference bevel surface length data Lb(θ) become minimum and the value of the outer circumference end face length data Ap(θ) becomes maximum becomes the reference angular position of the center part of the crystal orientation detection use flat surface 102.

Again, FIG. 12 will be returned to for the explanation. After identifying the rotational angular position θp, the processing unit 20 extracts angle θr in the angle information stored in the memory corresponding to the first semiconductor wafer 100-1 under processing (S24). Specifically, the processing unit 20 identifies, in the angle information stored in the memory, the angle information including the cassette ID, slot no., and time stamp linked with the first outer circumference bevel surface length data Ub(θ), outer circumference end face length data Ap(θ), and second outer circumference bevel surface length data Lb(θ) read at step S22 and extracts the angle θr at that identified angle information.

Next, the processing unit 20 adds the angle θr extracted at step S24 to the rotational angular position θp (reference angular position) identified at step S23 (S25). In the above-mentioned way, the rotational angular position θp identified at step S23 expresses the rotational angular position of the center part of the crystal orientation detection use flat surface 102, while the angle θr extracted at step S24 expresses the angle from the line connecting the center part of the flat surface 102 formed at the first semiconductor wafer 100-1 and the center of the circle of the first semiconductor wafer 100-1 to the crystal orientation of that first semiconductor wafer 100-1. Therefore, the angular position (θp+θr) comprised of the rotational angular position θp identified at step S23 plus the angle θr extracted at step S24 expresses the crystal orientation of the first semiconductor wafer 100-1.

Furthermore, the processing unit 20 controls the drive of the rotation drive motor 50 so as to make the crystal orientation acquired at step S25 match a preset predetermined orientation (S26). Due to this control, the rotation drive motor 50 is driven and the turntable 51 is turned, whereby the first semiconductor wafer 100-1 set at that turntable 51 turns and the crystal orientation of that first semiconductor wafer 100-1 matches a predetermined orientation. In this way, by matching the crystal orientation of the first semiconductor wafer 100-1 with a predetermined orientation, in the processing of the later CMP step, the processing of the bevel polishing step, etc., it is possible to treat the crystal orientation of the first semiconductor wafer 100-1 as being fixed.

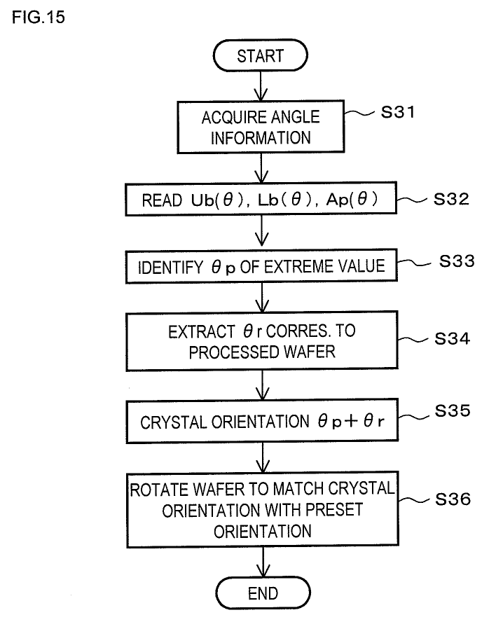

When the second semiconductor wafer 100-2 (see FIG. 3A and FIG. 3B) is used as the semiconductor wafer under inspection 100, the processing unit 20 performs a crystal orientation detection operation in accordance with the flow chart shown in FIG. 15.

In FIG. 15, the processing of step S31 to step S32 corresponds to the processing of step S21 to step S22 in FIG. 12. That is, the processing unit 20 first acquires angle information including the angle formed by the reference angular position (in the above-mentioned example, the position of the crystal orientation detection flat surface 102) and the crystal orientation (S31).

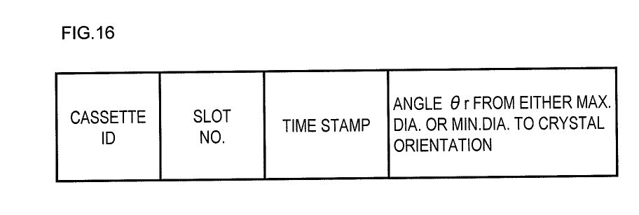

FIG. 16 is a view showing the angle information in this example. The angle information shown in FIG. 16 is comprised of the cassette ID, slot no., and time stamp for identifying the second semiconductor wafer 100-2 and the angle θr from the angular position of either the maximum diameter or minimum diameter of the second semiconductor wafer 100-2 (reference angular position) to the crystal orientation of that second semiconductor wafer 100-2. The angle information acquired by the processing unit 20 is stored in the memory.

Next, the processing unit 20 reads out the first outer circumference bevel surface length data Ub(θ), outer circumference end face length data Ap(θ), and second outer circumference bevel surface length data Lb(θ) stored at S14 of FIG. 11 (S32).

Furthermore, the processing unit 20 identifies the rotational angular position θp where the read first outer circumference bevel surface length data Ub(θ), outer circumference end face length data Ap(θ), and second outer circumference bevel surface length data Lb(θ) become extreme values, specifically, the rotational angular position θp where the values of the first outer circumference bevel surface length data Ub(θ) and second outer circumference bevel surface length data Lb(θ) become extremely large values and the value of the outer circumference end face length data Ap(θ) becomes an extremely small value or the rotational angular position θp where the values of the first outer circumference bevel surface length data Ub(θ) and second outer circumference bevel surface length data Lb(θ) become extremely small values and the value of the outer circumference end face length data Ap(θ) becomes an extremely large value (S33).

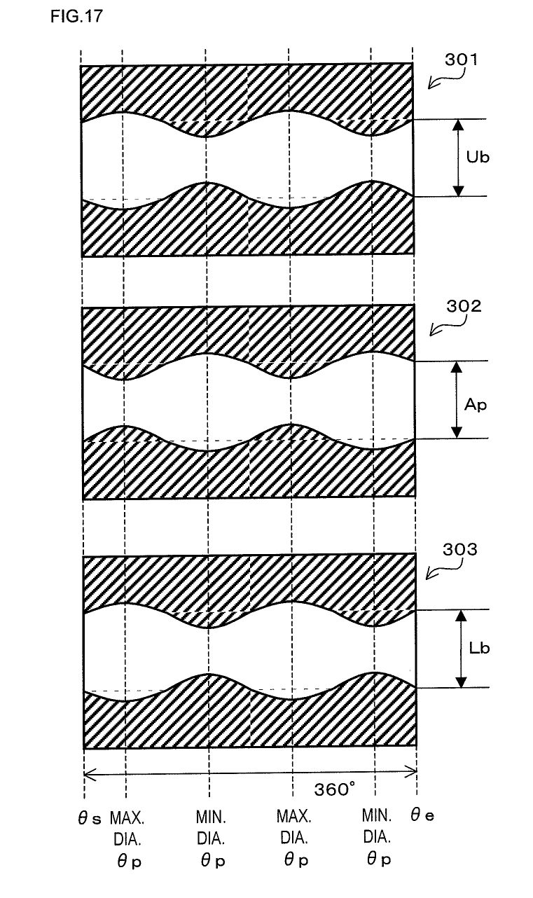

FIG. 17 is a view showing an image 301 of the first outer circumference bevel surface 101b, an image 302 of the outer circumference end face 101a, and an image 303 of the second outer circumference bevel surface 101c of the second semiconductor wafer 100-2 and the correspondence with the first outer circumference bevel surface length data Ub(θ), the outer circumference end face length data Ap(θ), and the second outer circumference bevel surface length data Lb(θ). As shown in FIG. 17, the image 301 of the first outer circumference bevel surface 101b, the image 302 of the outer circumference end face 101a, and the image 303 of the second outer circumference bevel surface 101c change in a wave form. Along with this, when the values of the first outer circumference bevel surface length data Ub(θ) and second outer circumference bevel surface length data Lb(θ) are extremely small values, the value of the outer circumference end face length data Ap(θ) becomes an extremely large value, while when the values of the first outer circumference bevel surface length data Ub(θ) and second outer circumference bevel surface length data Lb(θ) are extremely large values, the value of the outer circumference end face length data Ap(θ) becomes an extremely small value. This is due to the fact that the second semiconductor wafer 100-2 has a first main surface 100a and a second main surface 100b of round shapes, in particular circular shapes, while the outer circumference end face 101a extends in an elliptical shape to the circumferential direction where at the maximum diameter part, the width of the outer circumference end face 101a becomes narrower than other parts and the diametrical direction widths of the first outer circumference bevel surface 101b and second outer circumference bevel surface 101c become wider than other parts and, on the other hand, at the minimum diameter part, the width of the outer circumference end face 101a becomes broader than other parts and the diametrical direction widths of the first outer circumference bevel surface 101b and second outer circumference bevel surface 101c become narrower than other parts. Therefore, the rotational angular position θp where the values of the first outer circumference bevel surface length data Ub(θ) and second outer circumference bevel surface length data Lb(θ) become extremely small values and the value of the outer circumference end face length data Ap(θ) becomes an extremely large value expresses the rotational angular position where the diametrical direction widths and diameters of the first outer circumference bevel surface 101b and second outer circumference bevel surface 101c become minimum (for example, can be made the reference angular position), while the rotational angular position Op where the values of the first outer circumference bevel surface length data Ub(θ) and second outer circumference bevel surface length data Lb(θ) become extremely large values and the value of the outer circumference end face length data Ap(θ) becomes an extremely small value expresses the rotational angular position where the diametrical direction widths and diameters of the first outer circumference bevel surface 101b and second outer circumference bevel surface 101c become maximum (for example, can be made the reference angular position).

Again, FIG. 15 will be returned to for the explanation. After identifying the rotational angular position θp (reference angular position), the processing unit 20 extracts the angle θr in the angle information stored in the memory corresponding to the second semiconductor wafer 100-2 under processing in the same way as step S24 of FIG. 12 (S34).

Next, the processing unit 20 adds the angle θr extracted at step S34 to the rotational angular position θp (reference angular position) identified at step S33. In the above-mentioned way, the rotational angular position θp identified at step S33 expresses the rotational angular position where the diametrical direction widths of the first outer circumference bevel surface 101b and second outer circumference bevel surface 101c become maximum or minimum, while the angle θr extracted at step S34 expresses the angle from the rotational angular position where the diametrical direction widths and diameters of the first outer circumference bevel surface 101b and second outer circumference bevel surface 101c become maximum or minimum to the crystal orientation of the second semiconductor wafer 100-2. Therefore, the rotational angular position θp where the diametrical direction widths and diameters of the first outer circumference bevel surface 101b and second outer circumference bevel surface 101c become maximum plus the angle θr from that rotational angular position θp to the crystal orientation or the rotational angular position θp where the diametrical direction widths and diameters of the first outer circumference bevel surface 101b and second outer circumference bevel surface 101c become either maximum or minimum plus the angle θr from that rotational angular position θp to the crystal orientation expresses the crystal orientation of the second semiconductor wafer 100-2.

Furthermore, the processing unit 20 controls the drive of the rotation drive motor 50 so as to make the crystal orientation acquired at step S35 match a preset predetermined orientation in the same way as step S26 of FIG. 12. Due to this control, the rotation drive motor 50 is driven and the turntable 51 is turned, whereby the second semiconductor wafer 100-2 set at that turntable 51 turns and the crystal orientation of that second semiconductor wafer 100-2 matches a predetermined orientation (S36).

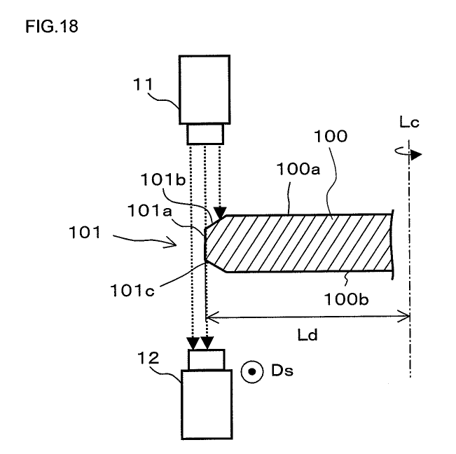

FIG. 18 is a view showing an example of arrangement of a light projecting unit 11 and light receiving unit 12 in a semiconductor wafer processing apparatus.

The semiconductor wafer 100 is, for example, set on a turntable 51 (not shown in FIG. 18) and can rotate together with that turntable 51 about its axis of rotation Lc. The light projecting unit 11 is set so as to face the first main surface 100a side of the outer circumference edge part 101 of the semiconductor wafer 100 set at the turntable, while the light receiving unit 12 is set so as to face the second main surface 100b side of the outer circumference edge part 101. The light projecting unit 11 projects light toward the outer circumference edge part 101 and its vicinity. The projected light is partially reflected at the semiconductor wafer 100, but the rest of the light reaches the light receiving unit 12 and is received by that light receiving unit 12.

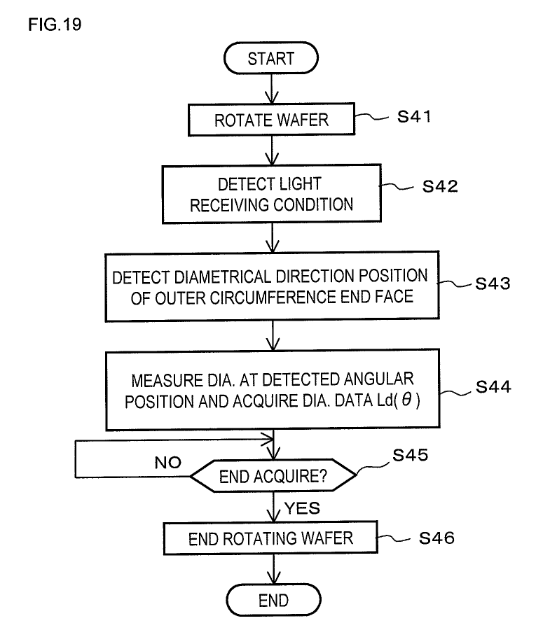

Next, the operation of the processing unit 20 will be explained. FIG. 19 is a flow chart showing a diameter detection operation executed by the processing unit 20.

The processing unit 20 makes the turntable 51 on which the semiconductor wafer 100 is set rotate by a predetermined speed (S41). In the process of the semiconductor wafer 100 rotating, the processing unit 20 makes the light projecting unit 11 project light and detects the light receiving state of the light receiving unit 12 (S42). Furthermore, the processing unit 20 detects the diametrical direction position of the outer circumference end face 101a of the semiconductor wafer 100 from the detected light receiving state and stores that position information in a predetermined memory (not shown) (S43).

Specifically, as explained above, the light projected by the light projecting unit 11 is partially reflected at the semiconductor wafer 100, but the rest of the light reaches the light receiving unit 12 and is received by that light receiving unit 12. Therefore, the light receiving state at the light receiving unit 12 greatly changes in amount of light at the position of the outer circumference end face 101a. For this reason, the processing unit 20 can detect a position where the amount of light changes by a predetermined value or more as the diametrical direction position of the outer circumference end face 101a at the different rotational angular positions θ of the circumferential direction (Ds) from the start position θs (θ=0°) to the same position one turn from the same, that is, the end position θe (360°). Here, the diametrical direction position is expressed by the distance from the reference position to where the amount of light at the light receiving surface changes by a predetermined value or more when assuming the center part of the light receiving surface of the light receiving unit 12 to be the reference position and the amount of light changes by a predetermined value or more at the side far from the axis of rotation Lc of the turntable 51 from that reference position and is expressed by the distance from the reference position to where the amount of light at the light receiving surface changes by a predetermined value or more multiplied by −1 when the amount of light changes by a predetermined value or more at the side near to the axis of rotation Lc of the turntable 51 from that reference position.

Furthermore, the processing unit 20 measures the diameter of the semiconductor wafer 100 at the angular position 8 of the outer circumference end face 101a for which the diametrical direction position has been detected and acquires diameter data Ld(θ) expressing that diameter (S44). Specifically, the processing unit 20 holds the distance from the reference position constituted by the center part of the light receiving surface of the light receiving unit 12 to the axis of rotation Lc of the turntable 51 and adds to that distance the diametrical direction position of the outer circumference end face 101a detected at the different rotational angular positions θ at step S43 to generate the diameter data Ld(θ). The generated diameter data Ld(θ) is stored in the memory.

The processing unit 20, in the process of the above-mentioned processing, judges if the diameter data of one turn of the semiconductor wafer 100 has finished being acquired (stored in the memory) (S45). If diameter data of one turn of the semiconductor wafer 100 has finished being acquired (YES at S45), the processing unit 20 makes the rotation of the turntable 51 on which the semiconductor wafer 100 is set stop (S46).

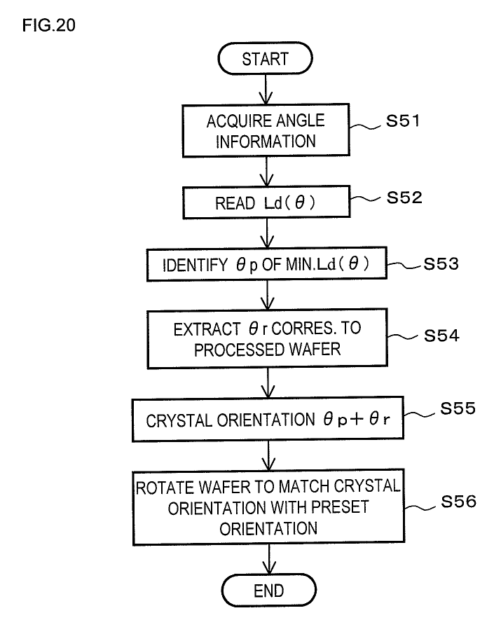

FIG. 20 is a flow chart showing a crystal orientation detection operation of the semiconductor wafer 100 by the processing unit 20. In this case, as the semiconductor wafer under inspection 100, the first semiconductor wafer 100-1 (see FIG. 2A and FIG. 2B) is used.

The processing unit 20, in the same way as step S21 of FIG. 12, obtains angle information, stored in the memory, including a predetermined angle formed by the position of the crystal orientation detection use flat surface 102 (reference angular position) and the crystal orientation (S51). The angle information is similar to that shown in FIG. 13. The angle information acquired by the processing unit 20 is stored in the memory.

Next, the processing unit 20 reads the diameter data Ld(θ) stored in the memory at step S44 of FIG. 19 (S52). Furthermore, the processing unit 20 identifies the rotational angular position θp where the read diameter data Ld(θ) becomes minimum (S53).

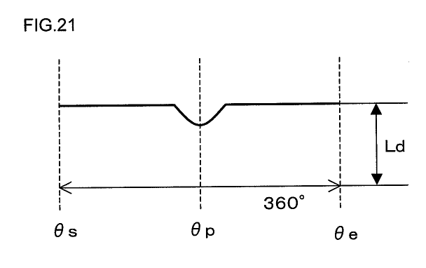

FIG. 21 is a view showing the change of the diameter data Ld(θ) of the first semiconductor wafer 100-1 with respect to the angular position. As shown in FIG. 21, the diameter data Ld(θ) becomes minimum at the part corresponding to the rotational angular position θp. This is because a crystal orientation detection use flat surface 102 having the rotational angular position θp as its center part is formed at the rotational angular position θp of the outer circumference edge part 101, so the diameter becomes minimum at that rotational angular position θp. Therefore, the rotational angular position θp where the diameter data Ld (θ) becomes minimum expresses the reference angular position of the center part of the crystal orientation detection use flat surface 102.

Again, FIG. 20 will be returned to for the explanation. After identifying the angular position θp (reference angular position), the processing unit 20 extracts the angle θr in the angle information stored in the memory corresponding to the first semiconductor wafer 100-1 under processing (S54).

Next, the processing unit 20 adds the angle θr extracted at step S54 to the rotational angular position θp identified at step S53. In the above-mentioned way, the rotational angular position θp identified at step S53 expresses the rotational angular position of the center part of the crystal orientation detection flat surface 102, while the angle θr extracted at step S54 expresses the angle from the line connecting the center part of the first semiconductor wafer 100-1 and the center of the circle of that semiconductor wafer 100-1 to the crystal orientation of that first semiconductor wafer 100-1. Therefore, the rotational angular position θp identified at step S53 plus the angle θr extracted at step S54 expresses the crystal orientation of the first semiconductor wafer 100-1.

Furthermore, the processing unit 20 controls the drive of the rotation drive motor 50 so as to make the crystal orientation acquired at step S55 match a preset predetermined orientation. Due to this control, the rotation drive motor 50 is driven and the turntable 51 is turned, whereby the first semiconductor wafer 100-1 set at that turntable 51 rotates and the crystal orientation of that first semiconductor wafer 100-1 matches a predetermined orientation (S56).

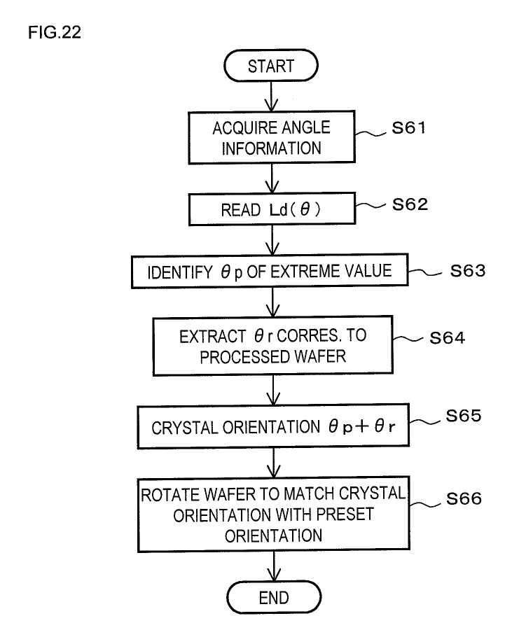

FIG. 22 is a flow chart showing crystal orientation detection operations for the second semiconductor wafer 100-2 (see FIG. 3A and FIG. 3B) and third semiconductor wafer 100-3 (see FIG. 4) by the processing unit 20.

The processing of step S61 to step S62 is similar to the processing of step S51 to step S52 of FIG. 20. That is, the processing unit 20 obtains angle information stored in the memory including the predetermined angle formed by the angular position of either the maximum diameter or minimum diameter (reference angular position) and the crystal orientation (see FIG. 16) (S61). The angle information obtained by the processing unit 20 is stored in the memory. Next, the processing unit 20 reads the diameter data Ld(θ) stored in the memory at step S44 of FIG. 19 (S62).

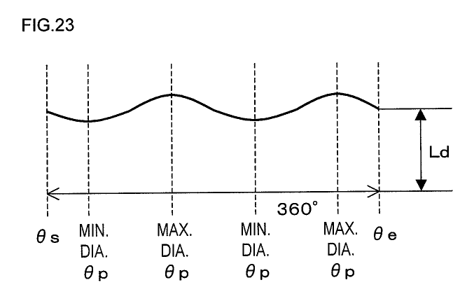

Furthermore, the processing unit 20 identifies a rotational angular position θp where the diameter data Ld (θ) becomes an extreme value (either extremely large value or extremely small value) as the reference angular position (S63). FIG. 23 is a view showing the change in the diameter data Ld(θ) of the second semiconductor wafer 100-2 (third semiconductor wafer 100-3) with respect to the angular position. The second semiconductor wafer 100-2 (third semiconductor wafer 100-3) has an outer circumference end face 100a extending out in an elliptical shape. Therefore, as shown in FIG. 23, the diameter data Ld(θ) changes in a wave manner along with movement of the angular position, becomes an extremely large value at the rotational angular position θp where the diameter becomes maximum, and becomes an extremely small value at the rotational angular position θp where the diameter becomes minimum.

Again, FIG. 22 will be returned to for the explanation. After identifying the rotational angular position θp where the diameter data Ld (θ) becomes an extreme value, the processing unit 20 extracts an angle θr corresponding to the second semiconductor wafer 100-2 under processing (third semiconductor wafer 100-3) in the angles θr in the angle information stored in the memory (S64).

Next, the processing unit 20 adds the angle θr extracted at step S64 to the rotational angular position θp identified at step S63. In the above-mentioned way, the rotational angular position θp identified at step S63 expresses the rotational angular position where the diameter becomes maximum or minimum, while the angle θr extracted at step S64 expresses the angle from the rotational angular position where the diameter becomes maximum or minimum to the crystal orientation. Therefore, the rotational angular position θp identified at step S63 (reference angle position) plus the angle θr extracted at step S64 expresses the crystal orientation of the second semiconductor wafer 100-2 (third semiconductor wafer 100-3).

Furthermore, the processing unit 20 controls the drive of the rotation drive motor 50 so as to make the crystal orientation acquired at step S65 match a preset predetermined orientation. Due to this control, the rotation drive motor 50 is driven and the turntable 51 is turned, whereby the second semiconductor wafer 100-2 (third semiconductor wafer 100-3) set at that turntable 51 rotates and the crystal orientation of that second semiconductor wafer 100-2 (third semiconductor wafer 100-3) matches a predetermined orientation (S66).

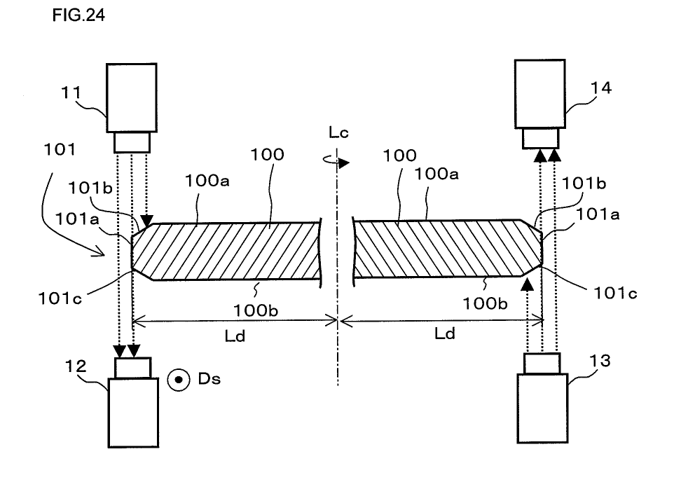

Note that, as shown in FIG. 24, it is also possible to provide two sets of light projecting units and light receiving units. In FIG. 24, a light projecting unit 11 is set so as to face the first main surface 100a side of the outer circumference edge part 101 of the semiconductor wafer 100 set at the turntable and a light receiving unit 12 is set so as to face the second main surface 100b side of the outer circumference edge part 101, while at a position rotated 180° from the set position of the light receiving unit 12, a light projecting unit 13 is set so as to face a second main surface 100b side of the outer circumference edge part 101 of the semiconductor wafer 100 and at a position rotated 180° from the set position of the light projecting unit 11, a light receiving unit 14 is set so as to face the first main surface 100a side of the outer circumference edge part 101. The light projecting unit 13 projects light toward the outer circumference edge part 101 and its vicinity. The projected light is partially reflected at the semiconductor wafer 100, but the rest of the light reaches the light receiving unit 14 and is received by that light receiving unit 14. By configuring the invention in this way, by just making the semiconductor wafer 100 rotate half way (180°), the diametrical direction position of the outer circumference end face 101a is obtained over the entire circumference of the semiconductor wafer 100.

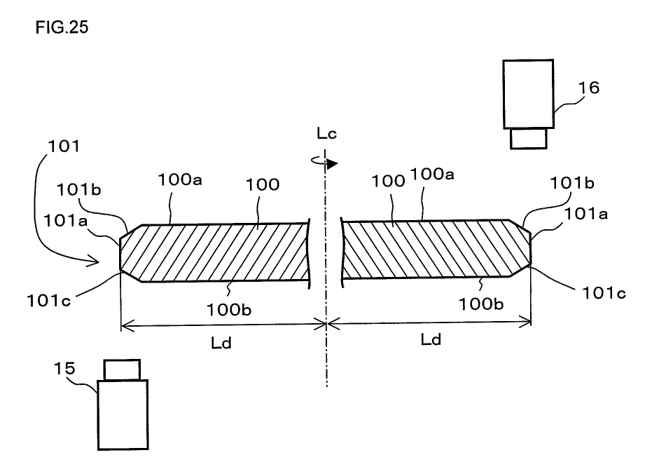

Further, as shown in FIG. 25, instead of the light projecting unit 11 and light receiving unit 12, it is also possible to use two CCD cameras. In FIG. 25, a first CCD camera 15 forming part of the imaging unit is set so as to face the second main surface 100b side of the outer circumference edge part 101 of the semiconductor wafer 100 set at the turntable, while a second CCD camera 16 forming part of the imaging unit is set so as to face the first main surface 100a side of the outer circumference edge part 101 of the semiconductor wafer 100 at a position rotated 180° from the set position of that first CCD camera 15.

At the different angular positions in the process of the semiconductor wafer 100 turning, CCD line sensors (not shown) in the first CCD camera 15 and second CCD camera 16 successively scan (sub scan) the semiconductor wafer 100 in the diametrical direction. Due to this, the first CCD camera 15 and second CCD camera 16 successively capture images of the semiconductor wafer 100 in the diametrical direction and output image signals in pixel units.

The processing unit 20 identifies the diametrical direction position of the outer circumference end face 101a of the semiconductor wafer 100 at different rotational angular positions θ of the circumferential direction from the start position θs (θ=0° to the same position one turn from the same, that is, the end position θe (360°), from the image signals from the first CCD camera 15 and the second CCD camera 16, measures the diameter at that diametrical direction position, and acquires diameter data Ld(θ) showing that diameter. Note that since the second CCD camera 16 is set at a position rotated 180° from the first CCD camera 15, in the same way as above, by just rotating the semiconductor wafer 100 by half a turn (180°), the diametrical direction positions of the outer circumference end face 101a are obtained over the entire circumference of the semiconductor wafer 100. After that, by performing the processing from step S45 of FIG. 19 and the processing of FIG. 20 and FIG. 22, the crystal orientation of the semiconductor wafer 100 is obtained. Furthermore, by displaying an image according to the image signal obtained by the imaging operation on the monitor 40, the condition of the outer circumference edge part 101 can be confirmed.

In this way, the first semiconductor wafer 100-1 of the present embodiment is formed at part of its outer circumference edge part 101 with a crystal orientation detection use flat surface 102 at a position forming a predetermined angle with respect to the crystal orientation (reference angular position) without influencing the shapes of the first main surface 100a and second main surface 100b (circular, elliptical, or other round shapes). Further, the second semiconductor wafer 100-2 has an outer circumference end face 101a at the outer circumference edge part 101 extending out in an elliptical shape with a maximum diameter part at which the width of the outer circumference end face 101a becomes narrower than other parts and at which the diametrical direction widths of the first outer circumference bevel surface 101b and second outer circumference bevel surface 101c become broader than other parts and, on the other hand, with a minimum diameter part at which the width of the outer circumference end face 101a becomes broader than other parts and at which the diametrical direction widths of the first outer circumference bevel surface 101b and second outer circumference bevel surface 101c become narrower than other parts. The position at which the diametrical direction widths of the first outer circumference bevel surface 101b and second outer circumference bevel surface 101c become either maximum or minimum, in other words, the position of either the maximum diameter or minimum diameter (reference angular position) forms a predetermined angle with respect to the crystal orientation. Further, the third semiconductor wafer 100-3 has an outer circumference end face 101a extending out in an elliptical shape and has the angular position of either the maximum diameter or minimum diameter (reference angular position) form a predetermined angle with respect to the crystal orientation.

Since the semiconductor wafers 100-1 to 100-3 have such a configuration, at the part of the identifiable reference angular position, there will be no great difference in process conditions or structure from other parts like with a U-shaped or V-shaped notch, so there will be no cause of contamination or inefficiency of shaping of the end face caused. Furthermore, this will not become a source of generation of dust such as with a mark, so it is possible to suitably set an indicator expressing the crystal orientation at the semiconductor wafer.

Further, the semiconductor wafer processing apparatus can identify the rotational angular position θp where the first outer circumference bevel surface length data Ub(θ) and second outer circumference bevel surface length data Lb(θ) of the first semiconductor wafer 100-1 become minimum as the reference angular position and can add to that rotational angular position θp an angle θr within the angle information to detect the crystal orientation. Further, the semiconductor wafer processing apparatus can identify the rotational angular position θr where the first outer circumference bevel surface length data Ub(θ), outer circumference end face length data Ap(θ), and second outer circumference bevel surface length data Lb(θ) of the second semiconductor wafer 100-2 become extreme values as the reference angular position and can add to that rotational angular position θr an angle θr within the angle information to detect the crystal orientation.

Furthermore, the semiconductor wafer processing apparatus can identify the rotational angular position θp where the diameter data Ld(θ) of the first semiconductor wafer 100-1 becomes minimum as the reference angular position and can add to that rotational angular position θp an angle θr within the angle information to detect the crystal orientation. Further, the semiconductor wafer processing apparatus can identify the rotational angular position θp where the diameter data Ld (θ) of the second semiconductor wafer 100-2 and third semiconductor wafer 100-3 become extreme values as a reference angular position and can add to that rotational angular position θp an angle θr within the angle information to detect the crystal orientation.

Note that the semiconductor wafer processing apparatus according to the above-mentioned embodiments detected the crystal orientation of a semiconductor wafer 100 under inspection, but the semiconductor wafer processing apparatus according to the present invention need only detect a reference angular position.

### INDUSTRIAL APPLICABILITY

The semiconductor wafer according to the present invention has an indicator showing a reference angular position suitably set. Furthermore, the semiconductor wafer processing apparatus and reference angular position detection method according to the present invention can detect that reference angular position. These are useful as a semiconductor wafer, semiconductor wafer processing apparatus, and reference angular position detection method.

1. A semiconductor wafer processing apparatus processing a semiconductor wafer set with a reference angular position at its circumferential direction while rotating it, having
an outer circumference edge information generating means for detecting a shape or diameter of an outer circumference edge part at a plurality of rotational angular positions of said semiconductor wafer and generating outer circumference edge information showing the shape or diameter at the rotational angular positions and
a reference angular position detecting means for detecting said reference angular position of said semiconductor wafer where said outer circumference edge part has a predetermined shape or has a predetermined diameter based on said outer circumference edge information generated for said plurality of rotational angular positions.

2. A semiconductor wafer processing apparatus as set forth in claim 1, further having a crystal orientation identifying means for identifying a crystal orientation of said semiconductor wafer based on a reference angular position detected by said reference angular position detecting means.

3. A semiconductor wafer processing apparatus as set forth in claim 1, wherein said outer circumference edge information generating means has:
an imaging unit arranged facing an outer circumference edge part of said semiconductor wafer, capturing an image of said outer circumference edge part in the circumferential direction, and outputting an image signal and
an image information generating means for generating image information of the outer circumferential edge part of said semiconductor wafer from the image signal output from said imaging unit, and
wherein said semiconductor wafer processing apparatus generates information showing the shapes at said plurality of rotational angular positions of said outer circumference edge part from said image information as said outer circumference edge information.

4. A semiconductor wafer processing apparatus as set forth in claim 3, wherein
said imaging unit captures images of a plurality of surfaces forming said outer circumference edge part and outputs corresponding image signals and
said outer circumference edge information generating means generates said outer circumference edge information from image information corresponding to said plurality of surfaces forming said outer circumference edge part.

5. A semiconductor wafer processing apparatus as set forth in claim 1, wherein
said outer circumference edge information generating means generates information showing the shapes of said plurality of rotational angular positions of said semiconductor wafer as said outer circumference edge information, and
said reference angular position detecting means may detect a rotational angular position giving a predetermined diameter as said reference angular position based on said outer circumference edge information at the different rotational angular positions.

6. A semiconductor wafer processing apparatus as set forth in claim 1, wherein said outer circumference edge information generating means has
a light projecting unit arranged facing a first main surface side of said outer circumference edge part of said semiconductor wafer and projecting light to said outer circumference edge part and its vicinity and
a light receiving unit arranged facing a second main surface side of said outer circumference edge part of said semiconductor wafer and receiving light from said light projecting unit and
generates information showing the diameters at said rotational angular positions from the light receiving state of said light receiving unit as said outer circumference edge information.

7. A semiconductor wafer processing apparatus as set forth in claim 1, wherein said outer circumference edge information generating means has:
an imaging unit arranged facing a first main surface side of said outer circumference edge part of said semiconductor wafer, successively capturing images of said outer circumference edge part in the circumferential direction, and outputting image signals and
an image information generating means for generating image information of said outer circumference edge part from the image signals from said imaging unit and
generates information showing the diameters at said plurality of rotational angular positions from said image information as said outer circumference edge information.

8. A reference angular position detection method detecting a reference angular position when processing a semiconductor wafer set with a reference angular position at its circumferential direction while rotating it, having
an outer circumference edge information generation step of detecting a shape or diameter of an outer circumference edge part at a plurality of rotational angular positions of said semiconductor wafer and generating outer circumference edge information showing the shape or diameter at the rotational angular positions and
a reference angular position detection step of detecting said reference angular position of said semiconductor wafer where said outer circumference edge part has a predetermined shape or has a predetermined diameter based on said outer circumference edge information generated for said plurality of rotational angular positions.

9. A reference angular position inspection method as set forth in claim 8, wherein
said outer circumference edge information generation step generates information showing the diameter at said outer circumference edge part as outer circumference edge information and
said reference angular position detection step detects a rotational angular position giving a predetermined diameter as said reference angular position based on said outer circumference edge information at the different rotational angular positions.

10. A semiconductor wafer to be processed by said semiconductor wafer processing apparatus as set forth in claim 1, wherein
a shape at a reference angular position of an outer circumference edge part formed of a first outer circumference bevel surface slanted from an outer edge of a first main surface, a second outer circumference bevel surface slanted from an outer edge of a second main surface at an opposite side from said first main surface, and an outer circumference end face differs from the shapes at the other angular positions within a range not influencing the shapes of said first main surface and said second main surface.

11. A semiconductor wafer as set forth in claim 10, wherein said outer circumference edge part is partially cut away at said reference angular position in a direction vertical to the diametrical direction of that semiconductor wafer within a range not influencing the shapes of said first main surface and said second main surface and a flat surface different from shapes at the other angular positions is formed at said reference angular position of said outer circumference end face.

12. A semiconductor wafer to be processed by said semiconductor wafer processing apparatus as set forth in claim 1, wherein
the outer circumference end face is formed into a uniform continuous curved surface and
the value of the diameter at said reference position differs from the values of the diameters at other angular positions.

13. A semiconductor wafer as set forth in claim 12, wherein the value of the diameter at the reference angular position is maximum.

14. A semiconductor wafer as set forth in claim 12, wherein the value of the diameter at the reference angular position is a minimum value.

15. A semiconductor wafer to be processed by said semiconductor wafer processing apparatus as set forth in claim 1, wherein
at an outer circumference edge part formed of a first outer circumference bevel surface slanted from an outer edge of a first main surface, a second outer circumference bevel surface slanted from an outer edge of a second main surface at an opposite side from said first main surface, and an outer circumference end face, a width of the diametrical direction of said first outer circumference bevel surface and a width of the diametrical direction of said second outer circumference bevel surface at said reference angular position differ from the corresponding widths of the diametrical direction at other angular positions.

16. A semiconductor wafer as set forth in claim 15, wherein the width of the diametrical direction of said first outer circumference bevel surface and the width of the diametrical direction of said second outer circumference bevel surface at said reference angular position are maximum.

17. A semiconductor wafer as set forth in claim 15, wherein the width of the diametrical direction of said first outer circumference bevel surface and the width of the diametrical direction of said second outer circumference bevel surface at said reference angular position are minimum.
